(19) United States
(12) Patent Application Publication
(10) Pub. No.: US 2010/0309643 A1
(43) Pub. Date: Dec. 9, 2010

(54) MULTI-CHIP HYBRID-MOUNTED DEVICE AND METHOD OF MANUFACTURING THE SAME

(76) Inventor: Rene Todt, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/735,718

(22) PCT Filed: Mar. 27, 2008
(86) PCT No.: PCT/JP2008/056625

§ 371 Date: Aug. 12, 2010

(51) Int. Cl. H05K 7/02; H05K 3/34

(52) U.S. Cl. 361/808; 29/840

(57) ABSTRACT

A multi-chip hybrid-mounted device is provided that is fabricated by an extremely simple fabrication process, thereby enabling excellent reliability and yield. During the mounting process, the submount is kept at a bias temperature slightly below the solder melting point. For each chip to be mounted, an auxiliary heater element located adjacent to the actual mounting/soldering position is temporarily energized. Using a bias temperature, a local temperature increase of only a few degrees Celsius in the mounting/soldering area will initiate the soldering process and affix the chip. Such a small temperature increase is readily achieved by the laterally displaced heater element with only a minimal amount of thermal stress. The fabrication process is fully scalable and enables mounting of an arbitrarily large number of chips using only a single solder material.

### TECHNICAL FIELD

The present invention relates to a hybrid-mounted optical or optoelectronic device consisting of multiple chips that are mounted on a substrate chip by a soldering process with high precision and to a technique for manufacturing the same.

### BACKGROUND ART

Modern optical or optoelectronic devices commonly aim to achieve an increasing level of integration in order to enhance the device characteristics, to reduce the device dimensions, and to improve the cost-performance level.

In general, two different integration approaches can be distinguished: monolithic and hybrid integration. The former approach, monolithic integration, strives to integrate all desired functionalities in a single device, which usually results in highly complicated manufacturing processes as well as compromised device designs. On the other hand, the later approach, hybrid integration, is based on the conviction that optimum performance can be achieved by designing dedicated chips for each of the required functions and by subsequently combining those chips to form a device that provides the desired overall functionality. The resulting device, consisting of a multitude of individual chips, is referred to as multi-chip hybrid-mounted device.

For proper, efficient, and high-performance operation, optical or optoelectronic devices typically require a very high mounting precision (which is characterized by a positional deviation of for example less than 0.5 micrometer).

Commonly, the mounting processes involved in the fabrication of a multi-chip hybrid-mounted device rely on soldering processes to affix the optical or optoelectronic chips to a submount chip, which may be an optical or optoelectronic chip as well.

The positioning of the chips to be mounted on the submount may be carried out by so-called active alignment (where the device is being operated during alignment and device characteristics, such as output power or wavelength, are being monitored while positioning the device), passive alignment (where the device is not being operated during alignment and only alignment mark deviations are being monitored while positioning the device), or self alignment (where the device is fitted in some preformed mold that ensures proper alignment).

To achieve a high enough mounting precision, the chips to be mounted have in general to be mounted in a sequential order and the solder bonds of previously mounted chips should essentially be left unaltered by mounting processes carried out subsequently for other chips. It should be stressed that the requirement of leaving previously formed solder bonds practically unaltered is of uttermost importance. Any remelting or reflowing of the previously formed solder joints would lead to unpredictable and uncontrollable movements of the chips that would destroy the optical alignment, and thus, fatally impair the device functionality.

Several mounting techniques are known to the one skilled in the art that are in principle suitable for realizing a multi-chip hybrid-mounted device. In most methods (the first three described below), this is achieved by individually heating the solder bumps of each chip to be mounted beyond their melting temperature. In all of these methods, the local temperature around the relevant solder bumps is significantly increased (e.g. by more than 100 degrees Celsius), which commonly deteriorates the alignment accuracy owing to the differences in thermal expansion.

In a first method, the local temperature increase is achieved by using light (ultraviolet, visible, infrared) of high intensity to illuminate, and thereby, to heat the desired soldering area. This method is, however, only suitable if either the submount or the chip to be mounted is transparent for the illumination light and the solder respectively the material in direct thermal contact with the solder sufficiently absorbs the light. Hence, there are severe limitations with respect to suitable materials, device structures, and illumination light sources. Furthermore, the spatial resolution is poor, unless laser radiation is used (which brings along safety issues).

Similarly, in a second method, gas jets can be used to heat selected parts of the substrate chip to generate the desired temperature distribution. However, also this method suffers from poor spatial resolution and is thus only suitable for large chips (on the order of about one mm or larger) and not suitable for nanophotonic devices.

In a third method, (resistive) heater elements placed underneath the solder bumps and actuated by electric current flow are used to melt the corresponding solder bumps. While the spatial resolution is good in this method, it suffers from a complicated circuit layout, from a complicated structure, and reliability issues. First of all, having heater elements underneath the solder bump is highly undesirable with respect to reliability because the large stress generated when energizing the heater element is well-known to bring about reliability issues for many components. Additionally, the submount/device structure becomes more complicated, as for example the heater elements need to be electrically isolated from the solder materials and the heater elements have to be electrically connected to outside heater contact pads. This requires multiple stacked layers of metals and insulation materials, which apart from increasing the manufacturing cost due to a large number of additionally required processing steps, can readily deteriorate the reliability. Moreover, another drawback to be mentioned is that the very strong local temperature increase required to raise the temperature of the solder above its melting point deteriorates the alignment accuracy due to thermal expansion issues.

Finally, in a fourth method, each chip is soldered to the submount using various solder materials having different melting temperatures. In this method, the solder having the highest melting temperature has to be used for the first chip and subsequently the soldering temperature needs to be reduced from chip to chip to ensure that previously mounted chips remain securely aligned. Owing to the limited availability of suitable soldering materials as well as to the required differences in soldering temperature, this method is only applicable when mounting a very small number of chips and if different soldering materials can be tolerated, which is in many cases not acceptable for reliability reasons.

### DISCLOSURE OF THE INVENTION

An object of the present invention is to provide a device structure that enables hybrid mounting of a multitude of chips with high precision, while avoiding the above-mentioned shortcomings of the present art.

According to the present invention, there is provided a hybrid-mounted multi-chip device, comprising:

a submount to which a multitude of chips is mounted;

a plurality of chips which are mounted with high precision in a sequential mounting process to the submount by soldering;

a plurality of auxiliary heater elements, each one associated with a soldering area between a specific chip and the submount, and that are located in proximity to the soldering area but not in between the submount and the chips.

According to the present invention, there is provided a method for fabricating a hybrid-mounted multi-chip device, comprising the steps of:

preparing a submount to which a multitude of chips is mounted;

forming a plurality of auxiliary heater elements, each one associated with the soldering area between a specific chip and the submount, and that are located in proximity to the soldering area but not in between the submount and the chips;

mounting a plurality of chips with high precision in a sequential mounting process to the submount by soldering; and to this end each of the heater elements is temporarily being energized to raise a local temperature in the corresponding soldering area from the preset submount temperature level that is slightly below a solder melting point to above the melting point for creating a firm bond between the submount and the chip.

### EFFECTS OF THE INVENTION

According to the present invention, the auxiliary heater element raises the temperature in the soldering area only temporarily above the solder melting point in order to affix the corresponding chip. As each heater element is designed to have only an impact in a well-defined spatial region, the mounting process of a given chip does not have any significant influence on previously mounted and aligned chips. Therefore, the technique is fully scalable and allows in principle for mounting of any arbitrarily large number of chips.

For typical device dimensions, the technique according to the present invention applies to chips of a minimum length on the order of 100 micrometer. By using additionally heat guiding or insulating structures, it can be readily extended to devices even shorter than 100 micrometer. There is no upper limit to the device length.

Combining a simple, highly reliable device structure that allows for low-cost and high-volume manufacturing with a high-precision and scalable mounting technique, the invention as taught here is an extremely effective and powerful structure to be put into practical use.

### BRIEF DESCRIPTION OF THE DRAWING

FIG. 1 is a perspective view of a multi-chip hybrid-mounted device in accordance with the first embodiment of the present invention.

FIGS. 2A to 2C are illustrations for describing the multi-chip mounting technique and for depicting the hybrid-mounted device at different steps of the mounting procedure.

FIG. 3 is an illustration for describing the multi-chip hybrid-mounted device, depicting the position of the heater element and the heat distribution when the heater element is energized.

FIG. 4 is a perspective view of a multi-chip hybrid-mounted device in accordance with the second embodiment of the present invention.

FIG. 5 is an illustration for describing the multi-chip hybrid-mounted device in accordance with the third embodiment of the present invention.

FIG. 6A is a perspective view of a multi-chip hybrid-mounted device in accordance with the fourth embodiment of the present invention.

FIG. 6B is a cross-section of the mounting area of the device shown in FIG. 6A.

### BEST MODE FOR CARRYING OUT THE INVENTION

Embodiments of the present invention will be described referring to the accompanying drawings. The drawings are all schematic and not necessarily to scale, with some dimensions intentionally distorted to aid in clarity of exposition.

The invention will be taught relating to a tunable laser as disclosed in U.S. patent application US 2006/0198415 A1 by Yamazaki. It is needles to say that the multi-chip hybrid-mounted device structure and the technique for manufacturing the same as taught in the present invention is not at all limited in its applicability to the preferred embodiments described below but is useful for a multitude of optical and optoelectronic devices (such as for example for fixed-wavelength lasers, modulators, optical cross-connects, and optical switches, to name just a few) in various layouts and designs without changing the true spirit of the invention.

### First Embodiment

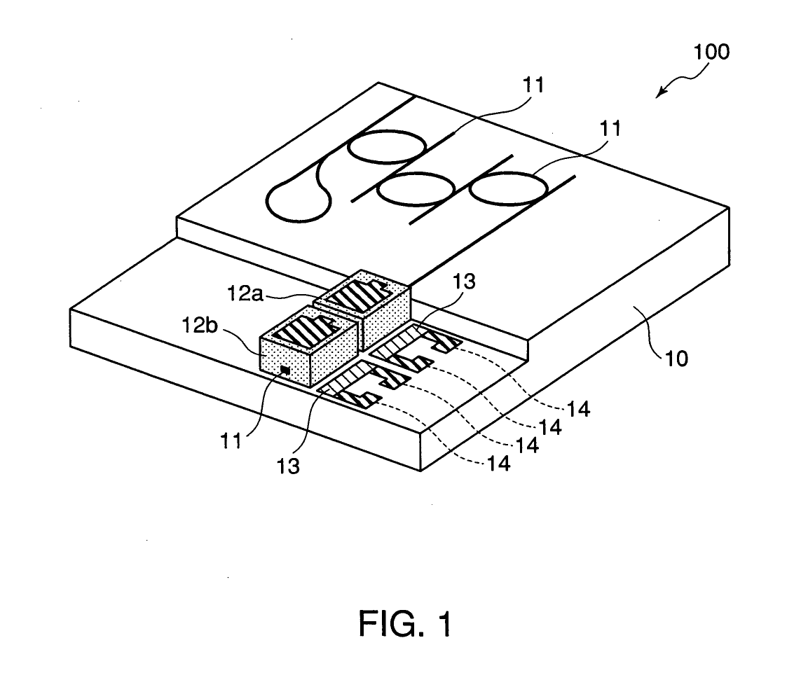

As shown in FIG. 1, the hybrid-mounted device 100 can for example comprises a submount 10 containing an optical waveguide 11 to which subsequently two chips 12a, 12b are aligned and mounted according to the present invention.

The heater elements 13 that are being used to generate a small local temperature increase that finally melts or reflows the solder are located outside the actual mounting and soldering area and do not have any overlap with the soldering area, thereby ensuring a simple fabrication process as well as excellent reliability and yield. For each mounted chip, there is a separate heater element 13 that is energized for bringing about the temperature increase required to melt the solder and fix the corresponding chip 12a, 12b on the submount 10.

In a preferred embodiment, the heater elements 13 are fabricated in form of resistive heaters with electrodes 14 attached to both ends used for contacting the heater element 13 when passing a current through it during the soldering process. The resistive heaters can, for example, be formed by a thin metal film or a thin semiconductor film.

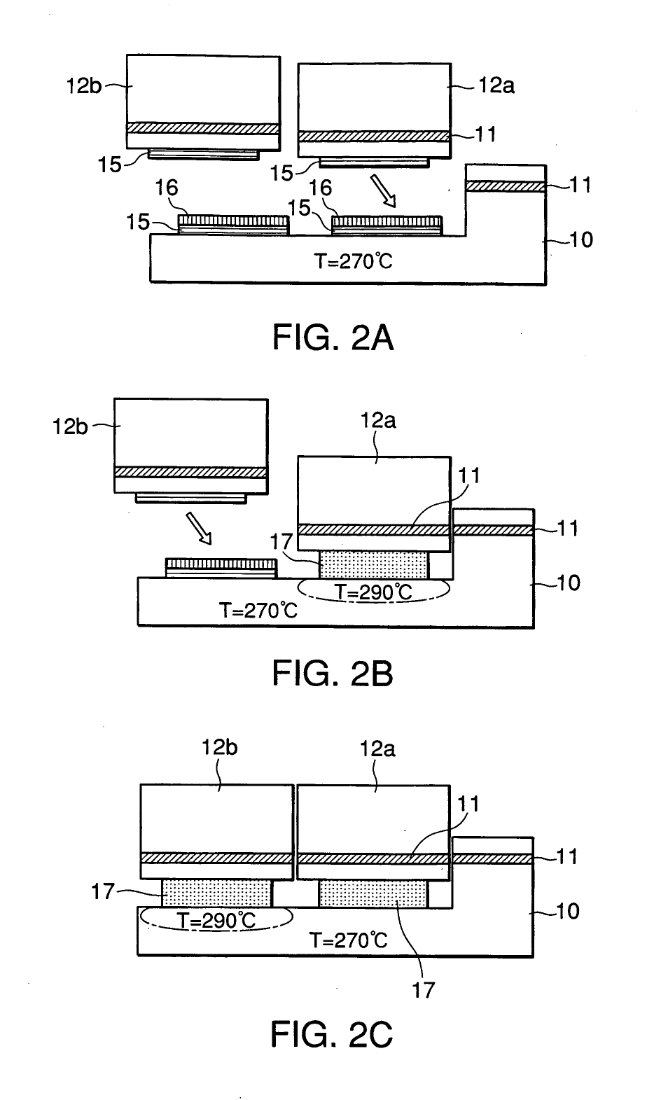

FIGS. 2A to 2C illustrate the mounting process in more detail.

First, the submount 10 as shown in FIG. 2A is prepared by conventional semiconductor technology processes. The submount 10 can be made of any suitable material that is easily processible and it contains a dedicated soldering or bonding area 15 for each chip 12a, 12b to be mounted. The soldering area 15 may, for example, consist of an Au layer covered with an Au/Sn solder layer 16 or bump. Due to their lateral displacement from the soldering area 15, the heater elements 13 shown in FIG. 1 are not visible in the cross-sectional views shown in FIGS. 2A to 2C. For mounting the first chip 12a, the submount 10 is put on a temperature-controlled stage that keeps the submount temperature constant at a temperature level slightly below the solder melting point. Assuming in the following for example a typical solder melting temperature of 280 degrees Celsius for the Au/Sn solder layer 16, the submount stage temperature would be set to 270 degrees Celsius. The heater element 13 located besides the soldering area 15 thus only needs to bring about a small temperature increase on the order of 10 degrees Celsius to solder the chip 12a to the submount 10.

Secondly, the first chip 12a to be mounted is aligned with the waveguide 11 on the submount 10 by any of the alignment methods described previously. Once the chip 12a has been aligned, the heater element 13 corresponding to the soldering area 15 of the chip 2a is being energized, as shown in FIG. 2B. The temperature in the soldering area 15 will, thus, rise and exceed the solder melting temperature. The solder will then become liquid and connect both the bonding area on the submount 10 and the bonding area on the chip 12a to be mounted. Subsequently, the heater element 13 will be turned off, the solder will cool and solidify, thereby forming a solder joint 17 (a firm bond) between the submount 10 and chip 12a.

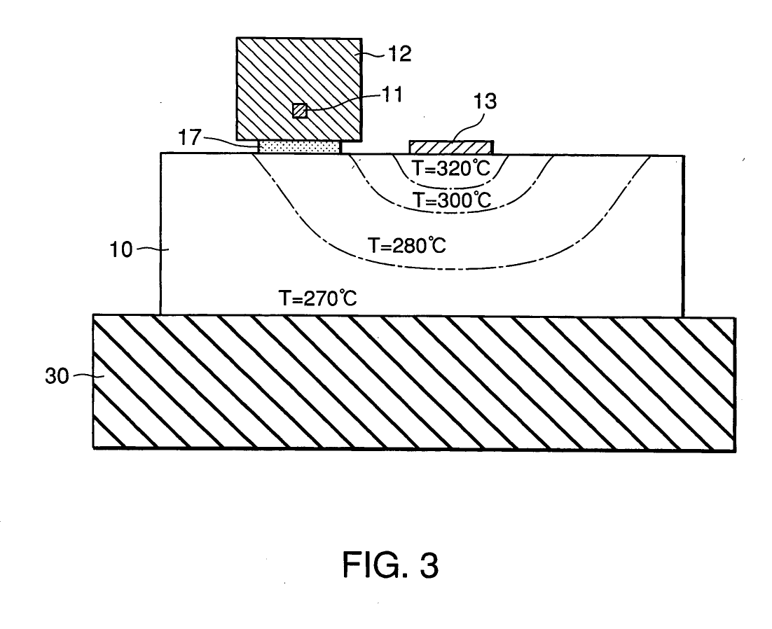

The schematic views in FIG. 2B and FIG. 3 illustrate the temperature distribution during this soldering process. Both the layout of the heater element 13 as well as the amount of current passed through it need to be chosen appropriately to achieve the desired temperature distribution. Optimization of these two parameters is readily achieved for a person skilled in the art. The illustration in FIG. 3 reveals also that there will be a temperature gradient between the laterally displaced heater element 13 and the soldering area 15.

Therefore, to achieve a local temperature increase in the soldering area 15 of about 10 degrees Celsius, a somewhat higher increase in the local temperature underneath the heater element 13 is required.

Exemplary simulations have confirmed that for a typical chip having a width of 100 micrometer and being mounted on a silicon substrate, a temperature increase by about 40 degrees Celsius just underneath the heater element 13 is sufficient to generate the desired temperature increase in the soldering area 15. Such a temperature increase is sufficiently small to avoid any deterioration of the alignment accuracy, reliability, or yield. Again it should be stressed that such a layout of the bonding area and the heater element 13 is only possible because of the bias temperature applied via the temperature-controlled stage 30, which minimizes the temperature increase required from the heater element 13.

Having mounted the first chip 12a, the mounting procedure continuous in exactly the same way with subsequent chips, in the present example with chip 12b, as shown in FIG. 2C. Hence, the second chip 12b will then be aligned, the solder in the corresponding soldering area 15 will be reflown by energizing the corresponding heater element 13. After the solder has formed a connection between the chip 12b and the submount 10, the heater element 13 will be turned off and the solder will be solidified again to form the solder joint 17 (a firm bond).

Having mounted all chips 12a, 12b, the submount 10 can be removed from the temperature-controlled stage 30, which completes the fabrication process for the multi-chip hybrid-mounted device.

### Second Embodiment

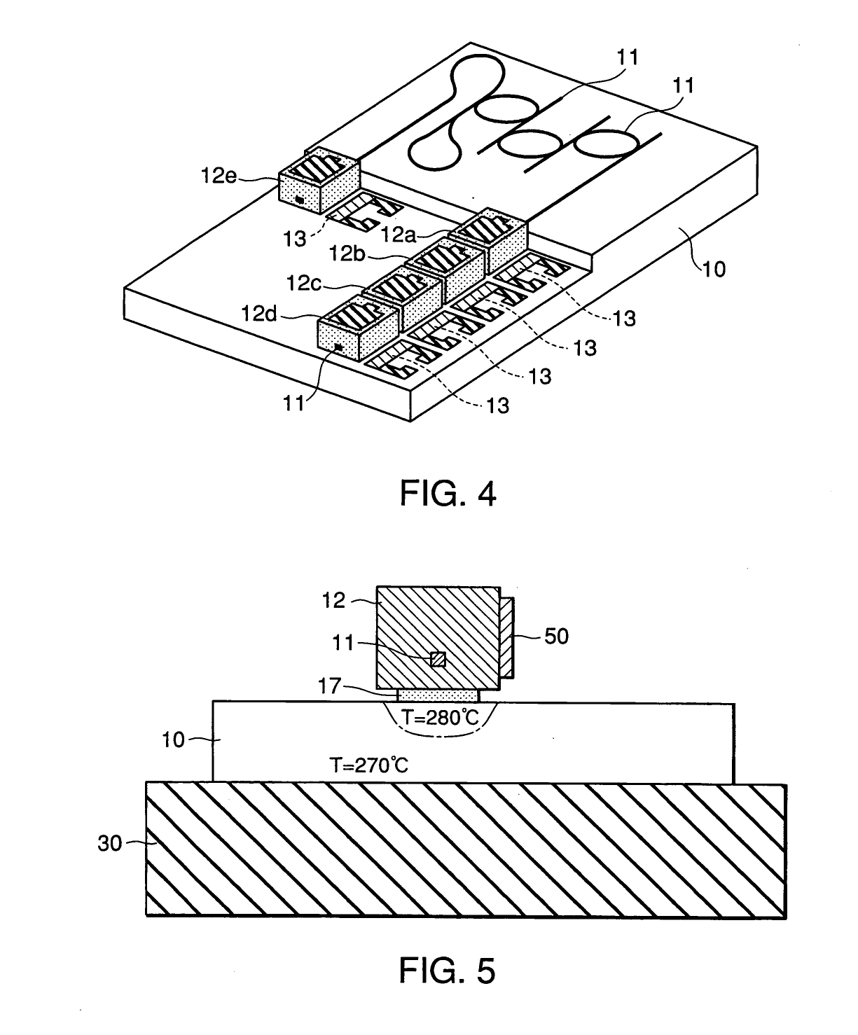

Another exemplary embodiment is depicted in FIG. 4 and illustrates the scalability of the mounting technique according to the present invention. The mounting process, as described above for the first embodiment for mounting of two chips 12a, 12b, can be employed in precisely the same way to mount any arbitrary large number of chips. In the present embodiment, a total of five chips 12a to 12e are mounted. Consequently, the submount 10 comprises five heater elements 13, each one associated to with a certain chip (12a to 12e). It should also be noted that the positions of the chips 12a to 12e are not limited to a certain geometrical layout, but can be positioned according to the requirements of the specific application as long as the layout leaves sufficient space for including a heater element 13 adjacent to each mounting position.

### Third Embodiment

In a third embodiment shown in FIG. 5, the auxiliary heater element 50 is positioned on the chip 12 to be mounted. The heater element 50 is still displaced from the mounting area and does neither compromise reliability and yield nor alignment precision and, thus, remains all advantages mentioned previously.

However, with the auxiliary heater element 50 being affixed to the chip 12 to be mounted, space on the submount 10 can be saved. Additionally, depending on the structure and thermal properties of the chip 12, the local temperature increase and, thus, the potential misalignment due to thermal stresses can be even further minimized.

### Fourth Embodiment

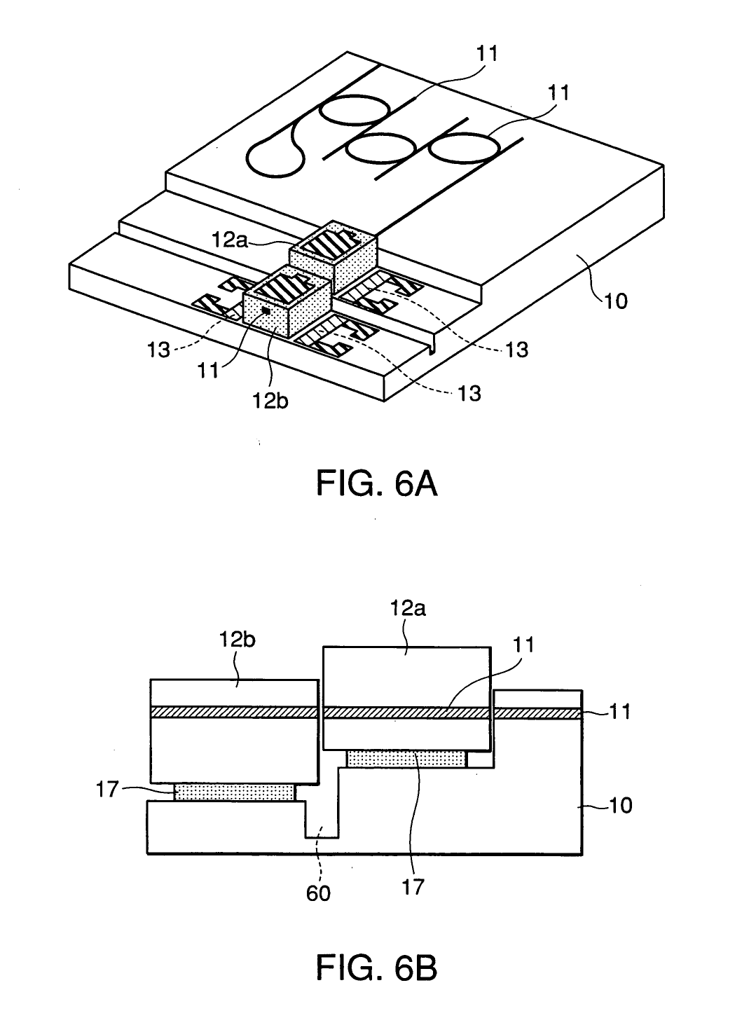

The fourth embodiment depicted in FIGS. 6A and 6B illustrates the use of additional techniques to tailor the heat flow in order to enhance the spatial resolution of the mounting technique according to the present invention.

One approach to improve the spatial resolution is the use of insulation trenches. Such a trench 60 has been etched in the present embodiment between chip 12a and chip 12b. As a consequence, the heat flow from the heater element 13 will be limited to the vertical and the lateral directions, thereby effectively reducing any influence of the heater element 13 associated with chip 12a on the solder joint 17 between the submount 10 and chip 12b. Obviously this holds vice versa also for the influence of the heater element 13 associated with chip 12b on the solder joint 17 between the submount 10 and chip 12a.

A further reduction of the thermal budget and, thus, of potential misalignment and thermal cross-talk is obtained by utilizing the heater elements 13 on each side of the mounting position (for chip 12b only in the present embodiment). Since heat will be supplied to the soldering area from two instead of only from one side, the maximum temperature increase required for a heater is reduced, which is certainly beneficial to even further minimize the adverse effects of thermal stresses.

As described above, the hybrid-mounted device 100 according to the present invention comprises a submount 10 that by itself may be an optical or optoelectronic chip, a multitude of chips 12a, 12b to be mounted in a sequential order by first positioning them on the submount 10 and subsequently fixing them by a soldering process, a multitude of solder bumps (or solder in some other form) used to affix the chips 12a, 12b to the submount 10, and a multitude of heater elements 13 that are associated with the chips 12a, 12b to be mounted and that are located outside the corresponding soldering area 15 of this chip 12.

The mounting process according to the present invention is carried out as follows: Initially the submount is placed on a temperature-controlled stage 30 that keeps the submount 10 temperature slightly (for example 10-30 degrees Celsius) below the solder melting point. Subsequently, the first chip 12a to be mounted is positioned on the submount 10 and aligned using either active, passive, or self alignment as described above. After the alignment is completed, the heater element 13 that is associated with the corresponding mounting position is energized to increase the local temperature in the soldering area 15 of this chip 12 beyond the solder melting point. After the solder has been melted and the solder joint 17 between the submount 10 and the chip 12 has been established, the corresponding heater element 13 is turned off again to solidify the solder joint 17. The same process of positioning, aligning, energizing of the corresponding heater element 13, and solidifying of the solder joint 17 is subsequently repeated in sequential order for all remaining chips 12 to be mounted.

The technique for fabricating a hybrid-mounted multi-chip device 100 according to the present invention is thus characterized by a soldering process that uses a combination of a so-called bias temperature bringing the submount 10, respectively the soldering areas 15, to a temperature just below the solder melting point and an auxiliary heater element 13 for each chip 12 to be mounted. Each auxiliary heater element 13 is spatial displaced from the mounting and soldering position of its corresponding chip 12 thereby enabling an easy to fabricate and highly reliable device structure. Additionally, the small thermal budget of only a few 10 degrees Celsius limits any thermal stresses to an absolute minimum, which is highly desirable and beneficial with respect to the alignment accuracy.

This is in contrast to the present art technique described above that uses heater elements directly underneath the soldering area. In that case, the device structure consisting of multiple stacked layers of insulators and metals is extremely complicated and the thermal budget is very considerable as the heater elements by themselves need to raise the temperature in the soldering area up to the melting point of the solder. For a typical AuSn solder, this results in a temperature increase in the soldering area by 260 degrees Celsius, creating an enormous amount of thermal stress that consequently impairs the alignment accuracy and reliability of the mounted chips. Thus, the present art technique that uses heater elements directly underneath the soldering area is clearly not suitable for high-volume products that require excellent reliability and yield.

According to the present invention, there is provided a hybrid-mounted multi-chip device, comprising:

a submount to which a multitude of chips is mounted;

a plurality of chips which are mounted with high precision in a sequential mounting process to the submount by soldering;

a plurality of auxiliary heater elements, each one associated with a soldering area between a specific chip and the submount, and that are located in proximity to the soldering area but not in between the submount and the chips.

Preferably, solder of the same type is used for all of the chips. Preferably, a distance between the heater element and the corresponding soldering area is smaller than 1 mm.

Preferably, a distance between the heater element and the corresponding soldering area is larger than 1 micrometer and smaller than 200 micrometer.

Preferably, the heater elements are formed by a metal film or a semiconductor film.

Preferably, the heater element is formed by a metal film of Pt, Au, or Ni/Cr.

Preferably, the heater element is formed by a semiconductor film of Si, InP, or GaAs.

Preferably, several heater elements are associated to the soldering area of the specific chip.

Preferably, a trench is formed on the submount to provide additional thermal insulation between the soldering area and the heater elements associated to a different soldering area.

Preferably, a thermal barrier is formed on the submount to provide additional thermal insulation between the soldering area and the heater elements associated to a different soldering area.

Preferably, a material of high thermal conductivity is used to enhance a heat flow from the heater element to the associated soldering area.

According to the present invention, there is provided a method for fabricating a hybrid-mounted multi-chip device, comprising the steps of:

preparing a submount to which a multitude of chips is mounted;

mounting a plurality of chips with high precision in a sequential mounting process to the submount by soldering; and

forming a plurality of auxiliary heater elements, each one associated with the soldering area between a specific chip and the submount, and that are located in proximity to the soldering area but not in between the submount and the chips,

wherein each of the heater elements is temporarily energized to raise a local temperature in the corresponding soldering area from the preset submount temperature level that is slightly below a solder melting point to above the melting point for creating a firm bond between the submount and the chip.

Preferably, the preset submount temperature level is controlled by an external device.

Preferably, the preset submount temperature level is less than 100 degrees Celsius below the solder melting point.

Preferably, the preset submount temperature is less than 50 degrees Celsius below the solder melting point.

Preferably, the preset submount temperature is more than 1 degrees Celsius and less than 30 degrees Celsius below the solder melting point.

Preferably, the chips to be mounted are aligned to the submount by an active, passive, or self alignment technique.

Although the present invention has been described in conjunction with a preferred embodiment thereof, the present invention is not limited to the embodiment described above. Various modifications and changes can be applied to the present invention without departing from the scope of the present invention. It goes without saying that such modifications and changes are to be included in the present invention.

For example, it should be noted that the heater elements need not necessarily be fabricated in the form of a simple stripe as depicted in all preceding embodiments, but can have complex shapes in order to tailor the temperature distribution.

Furthermore, also several heater elements could be utilized for each mounting position. Such an approach could, for example, be used to melt the solder only in a specific part of the soldering area. By consecutively reflowing different parts of the soldering area, the final solder joint can be formed with an extremely high mounting accuracy.

Finally it should be mentioned that the mounting areas do not have to lie in a flat plane as depicted in the preceding embodiment. Rather than that, the soldering areas may have any complex topology. For example, if the chips to be mounted have different heights or need to be aligned at different height levels (as illustrated in FIGS. 6A and 6B), the use of a step-like topology as in FIG. 6 is appropriate to ensure vertical alignment of the waveguides in the different chips.

1. A hybrid-mounted multi-chip device, comprising:
a submount to which a multitude of chips is mounted;
a plurality of chips which are mounted with high precision in a sequential mounting process to the submount by soldering; and
a plurality of auxiliary heater elements, each one associated with a soldering area between a specific chip and the submount, and that are located in proximity to the soldering area but not in between the submount and the chips.

2. The hybrid-mounted multi-chip device according to claim 1, wherein solder of the same type is used for all of the chips.

3. The hybrid-mounted multi-chip device according to claim 1, wherein a distance between the heater element and the corresponding soldering area is smaller than 1 mm.

4. The hybrid-mounted multi-chip device according to claim 1, wherein a distance between the heater element and the corresponding soldering area is larger than 1 micrometer and smaller than 200 micrometers.

5. The hybrid-mounted multi-chip device according to claim 1, wherein the heater elements comprise a metal film or a semiconductor film.

6. The hybrid-mounted multi-chip device according to claim 5, wherein the heater element comprises a metal film of Pt, Au, or Ni/Cr.

7. The hybrid-mounted multi-chip device according to claim 5, wherein the heater element comprises a semiconductor film of Si, InP, or GaAs.

8. The hybrid-mounted multi-chip device according to claim 1, wherein several heater elements are associated to the soldering area of a specific chip.

9. The hybrid-mounted multi-chip device according to claim 1, wherein a trench is formed on the submount to provide additional thermal insulation between the soldering area and the heater elements associated to a different soldering area.

10. The hybrid-mounted multi-chip device according to claim 1, wherein a thermal barrier is formed on the submount to provide additional thermal insulation between the soldering area and the heater elements associated to a different soldering area.

11. The hybrid-mounted multi-chip device according to claim 1, wherein a material of high thermal conductivity is used to enhance a heat flow from the heater element to the associated soldering area.

12. A method for fabricating a hybrid-mounted multi-chip device, comprising:
preparing a submount to which a multitude of chips is mounted;
forming a plurality of auxiliary heater elements, each one associated with the soldering area between a specific chip and the submount, and that are located in proximity to the soldering area but not in between the submount and the chips; and
mounting a plurality of chips with high precision in a sequential mounting process to the submount by soldering; and to this end each of the heater elements is temporarily being energized to raise a local temperature in the corresponding soldering area from the preset submount temperature level that is slightly below a solder melting point to above the melting point for creating a firm bond between the submount and the chip.

13. The method for fabricating a hybrid-mounted multi-chip device according to claim 12, wherein the preset submount temperature level is controlled by an external device.

14. The method for fabricating a hybrid-mounted multi-chip device according to claim 12, wherein the preset submount temperature level is less than 100 degrees Celsius below the solder melting point.

15. The method for fabricating a hybrid-mounted multi-chip device according to claims 12, wherein the preset submount temperature is less than 50 degrees Celsius below the solder melting point.

16. The method for fabricating a hybrid-mounted multi-chip device according to claims 12, wherein the preset submount temperature is more than 1 degree Celsius and less than 30 degrees Celsius below the solder melting point.

17. The method for fabricating a hybrid-mounted multi-chip device according to claim 12, wherein the chips to be mounted are aligned to the submount by an active, passive, or self alignment technique.
